(19) United States
(12) Patent Application Publication
(10) Pub. No.: US 2020/0382090 A1
(43) Pub. Date: Dec. 3, 2020

(54) INDUCTOR ASSEMBLY AND APPARATUS WITH IMPEDANCE MATCHING NETWORK

(71) Applicant: TOPANGA ASIA LIMITED, Kowloon (HK)

(72) Inventors: Wing Yiu LAM, New Territories (HK); Yuen Fat LEE, Kowloon (HK); Eddie Koon Chung LAU, North Point (HK)

(73) Assignee: TOPANGA ASIA LIMITED, Kowloon (HK)

(21) Appl. No.: 16/889,292

(22) Filed: Jun. 1, 2020

(30) Foreign Application Priority Data
May 31, 2019 (HK) 19124585.1

(51) Int. Cl. H03H 7/38; H03F 1/56; H05K 1/02

(52) U.S. Cl. CPC H03H 7/38; H03F 1/565; H05K 2201/1003; H05K 2201/10409; H05K 2201/10015; H05K 1/0251

(57) ABSTRACT

Examples include an inductor assembly and an apparatus comprising and a transistor amplifier and an impedance matching network. The impedance matching network comprises a circuit board, an inductance block and a screw. The inductance block has a first leg mounted on a first contact plate of the circuit board and a second leg mounted on a second contact plate of the circuit board. The screw is screwable into the inductance block such that a threaded portion of the screw engages with threaded portions of the first leg and the second leg to form a conductive path connecting the first contact plate with the second contact plate. The length of the conductive path and a value of the inductance of the conductive path are adjustable by adjusting a height of the screw within the inductance block.

The present disclosure relates to inductor assembly for impedance matching and an apparatus including a transistor amplifier and an impedance matching network.

### BACKGROUND

Impedance matching networks may be used to match the output impedance of the source of an electrical signal with the input impedance of an electrical load. For instance the source may be an amplifier and the load may be a device or circuit which is to receive the amplified signal. Matching the impedance of a source and a load may help to improve the power transfer and/or reduce signal reflection by the load.

Impedance is the sum of resistance and reactance. Impedance may be expressed in Cartesian form as Z=R+jX, where Z is the impedance, R is the resistance, X is the reactance and j is the imaginary unit. Alternatively impedance may be expressed in phasor form which represents the phase relationship between the time varying voltage and current of a signal due to the presence of inductance and capacitance, e.g. |Z|∠θ where the magnitude of Z is given by |Z|=\sqrt{R²+X²}, where the phase angle of θ is given by

$$θ = {tan}^{- 1} \frac{x}{R} .$$

FIG. 1 shows an example of a prior art impedance matching network 100, which includes an input 110, an output 190 and a variable capacitor 130 on an output side of the network. A transmission line connecting the input and the output may have a characteristic impedance represented by 125 in the diagram. A signal source 10 may be connected to the input 110 and a load 20 connected to the output 190. The impedance of the network 100 may be varied by adjusting the capacitance of the variable capacitor 130, so as to match the impedance of the source 10 with the impedance of the load 20.

For the best impedance matching, the impedance of the source should be the complex conjugate of the input impedance of the impedance matching network. For instance, if the impedance of the source is of value “A+Bj”, then the input impedance of impedance matching network should be tuned to the value “A−Bj”, in order to get minimum reflection for best matching.

The arrangement in FIG. 1 is convenient as variable capacitors are widely available, cheap and simple to manufacture. However, a problem with the arrangement of FIG. 1 is that, by adjusting the capacitor 130, both resistance and reactance component of the input of the matching network will change simultaneously which makes fine tuning difficult.

FIG. 2 illustrates a Smith chart 200 for impedance matching at 400 MHz for the impedance matching network of FIG. 1 and shows how capacitances of 1, 5, 9 and 12 pF lie on different constant resistance circles. For example, the 12 pF capacitance is near the Z₀=0.1 constant resistance circle, while the 1 pF capacitance is near the Z₀=0.3 constant resistance circle. Therefore tuning the capacitor between 1 and 12 pF will span the input impedance across different constant resistance circles (i.e. between constant resistance circle Z₀=0.3 and Z₀=0.1, where Z₀ is the impedance of the network). As both the real and imaginary components of the impedance change as the capacitance is adjusted this makes accurate fine tuning of the impedance matching difficult to achieve.

### BRIEF DESCRIPTION OF THE DRAWINGS

FIG. 1 is a circuit diagram of a prior art impedance matching network;

FIG. 2 is a Smith chart for different matching results with a variable capacitor;

FIG. 3 is a schematic diagram of an example apparatus according to the present disclosure;

FIG. 4A is a circuit diagram of an example apparatus according to the present disclosure;

FIG. 4B is a further circuit diagram of another example apparatus according to the present disclosure;

FIG. 5 is a Smith chart for different matching results with a variable inductor;

FIG. 6 is a diagram showing an example apparatus according to the present disclosure;

FIG. 7 is a diagram showing an example inductance block according to the present disclosure;

FIG. 8 is a diagram of the inductance block of FIG. 7 showing a conductive path;

FIG. 9 is a diagram of an example inductor assembly according to the present disclosure, showing a conductive path;

FIG. 10 is a diagram showing an example screw for use in an inductance block according to the present disclosure;

FIG. 11 is a diagram showing assembly of an apparatus according to the present disclosure;

FIG. 12 is a diagram of another example inductance block according to the present disclosure;

FIG. 13 is a diagram of another example inductance block according to the present disclosure; and

FIG. 14 is a diagram of another example inductance block according to the present disclosure;

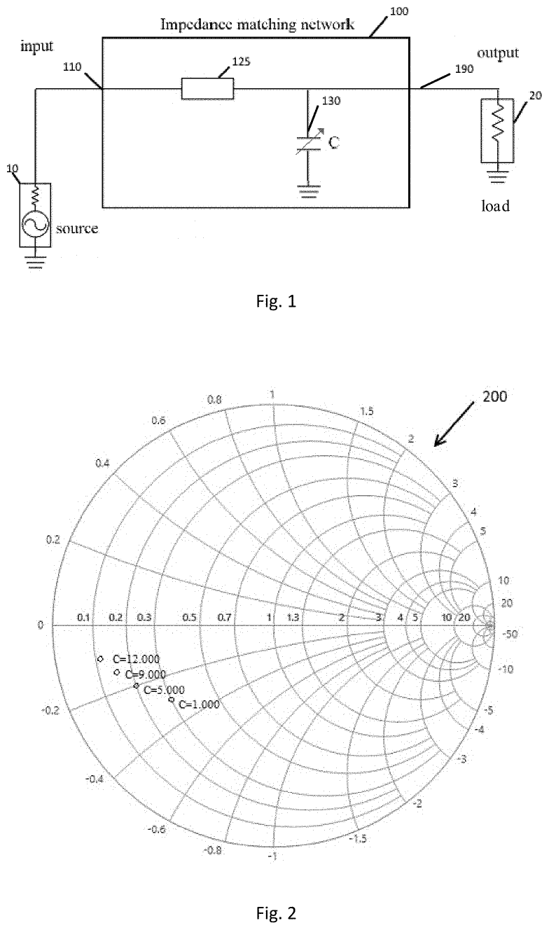

### DETAILED DESCRIPTION

One aspect of the present disclosure comprises an apparatus including a transistor amplifier and an impedance matching network. The impedance matching network comprises a circuit board, an inductance block and a screw. An output of the transistor amplifier is coupled to a first contact plate of the circuit board.

The inductance block includes a first leg mounted on and projecting upwardly from the first contact plate of the circuit board and a second leg mounted on and projecting upwardly from a second contact plate of the circuit board. The second leg is separated from the first leg by an air gap and the first leg and the second leg include threaded portions for receiving a screw.

The screw comprises a shaft with at least one threaded portion and is screwable into the inductance block such that the at least one threaded portion of the screw engages with the threaded portions of the first leg and the second leg.

The screw and the inductance block together form a conductive path connecting the first contact plate with the second contact plate via the first leg, the second leg and the at least one threaded portion of the screw which is in contact with the threaded portions of the first leg and the second leg.

The length of the conductive path and a value of the inductance of the conductive path are adjustable by adjusting a height of the screw within the inductance block. Thus, by adjusting the screw, the inductance and therefore the reactance or imaginary component of the impedance may be adjusted independently of the resistance. This facilitates fine tuning of the impedance matching.

An inductance block as described above may be relatively cheap and simple to manufacture compared to conventional variable inductors which comprise a wire wound around a ferrite core and a variable tap. Furthermore, the inductance block of the present disclosure may allow relatively precise adjustment of impedance. Whereas a conventional variable inductor with a coil and variable tap adjusts the impedance in stepped increments equal to one turn of the coil, the impedance of the inductance block of the present disclosure is not limited to fixed stepped increments and may be varied continuously by turning a screw.

The impedance block and the apparatus disclosed by the present application may be particularly useful in applications which use a high power transistor amplifier which delivers a high frequency signal to a load. In this context high power means 100 Watts or greater and high frequency means 100 MHz or greater. However, the present disclosure is not limited to high power applications and may be used with signal source powers as low as 1 Watt.

Conventional variable inductors comprising a ferrite core and wire wound around the core may encounter difficulties at high frequencies due to high losses in the ferrite core and may not be able to handle a signal which has both high power and frequency. This is because in order to have a wide tuning range, the wire has to be wound for a few turns around the core to form the inductor. However, to achieve a 10 nH inductor at 400 Mhz would require a 1 mm wide wire with a length of approximately 10 mm which is difficult to wind. A thicker wire of the same length would be even more difficult to wind and may have reduced inductance. Therefore, within the scope of typical tuning range e.g. 1-10 nH, the wire width of the conventional design are typically near 1 mm range. Such a thin wire may be damaged by large input currents, such as those generated by a high power transistor amplifier. However, an inductor block according to the present disclosure may be able to cope with a high frequency, high power signal and can dissipate heat through the surface area of the inductor block.

One example application for the impedance matching network of the present disclosure is in the field of electrodeless lamps, such as but not limited to electrodeless plasma lights which may be used for high bay lighting or plant lighting. Electrodeless plasma lamps excite a plasma inside a bulb with radio frequency power and may include a high power transistor amplifier which acts as a source of a radio frequency signal and a lamp structure including a bulb and gas inside the bulb which acts as a load. An impedance matching circuit may be used to match the impedance of the source and the load so as to minimize or reduce reflections between the source and the load. Other applications include cellular base stations to match a high power, high frequency amplifier with an antenna, high power welding equipment and medical devices which may use a high power, high frequency signal. However, the teachings of the present disclosure are not limited thereto and may be used in any application in which a signal source is to be impedance matched with a load.

The impedance matching network of the present disclosure includes at least one variable inductor which is formed by inductance block and the screw described above. In some examples the impedance matching network includes the variable inductor as the sole component, while in other examples the impedance matching network may include further components such as one or more open-stub capacitors and/or one or more fixed inductors.

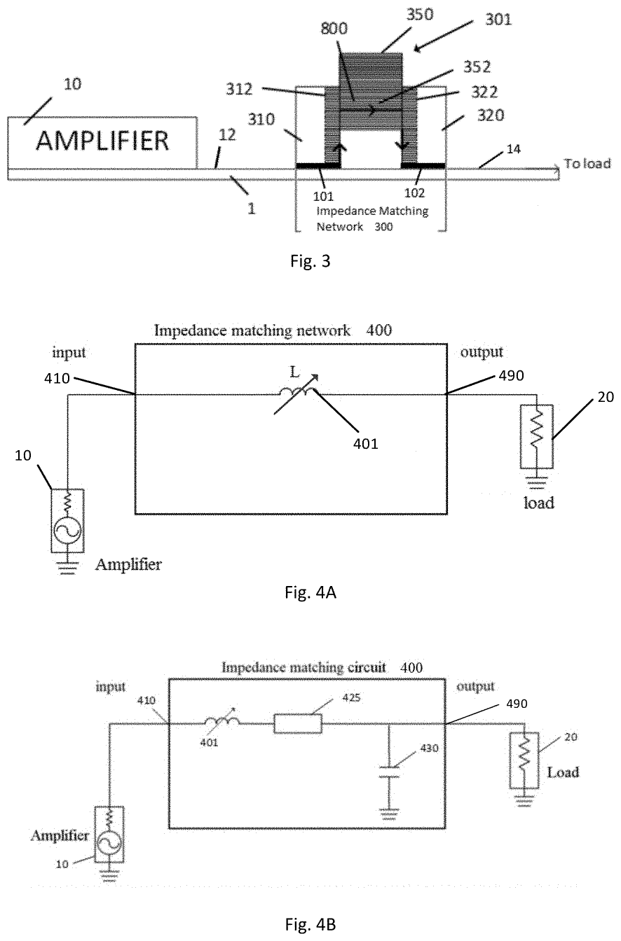

FIG. 3 is a schematic diagram showing an example of an apparatus according to the present disclosure, which comprises a transistor amplifier 10 and an impedance matching network 300. The impedance matching network 300 includes a circuit board 1 and an inductance block 301. The inductance block 301 includes a first leg 310 which is mounted on a first contact plate 101 of the circuit board and a second leg 320 mounted on a second contact plate 102 of the circuit board.

The circuit board 1 may for example be a printed circuit board (PCB) comprising an insulator substrate and metal traces embedded in the insulator substrate. The first and second contact plates 101 and 102 are electrically conductive and may be formed of a metal such as, but not limited to, copper or a copper alloy. The impedance block 301 is formed of an electrically conductive material and may be a metal, such as but not limited to copper, a copper alloy, iron or stainless steel etc.

The transistor amplifier 10 is electrically coupled to a first contact plate 101 of the circuit board, for example by a conductive path 12. The amplifier 10 generates a signal which passes through the inductance block 301 of the impedance matching network 300 before being output to a load. The inductance block 301 has a variable inductance which may be adjusted to match the internal impedance of the transistor amplifier 10 with the input impedance of the load.

The first leg 310 of the inductance block 301 is mounted on and projects upwardly from the first contact plate 101 of the circuit board 1, while the second leg 320 is mounted on and projects upwardly from the second contact plate 102. The second leg 320 is spaced apart and separated from the first leg 310 by an air gap. The first leg 310 and the second leg 320 include respective threaded portions 312, 322 for receiving a screw 350.

The screw 350 comprises a shaft with at least one threaded portion 352 and may be screwed into the inductance block 301. When the screw 350 is screwed into the inductance block 301, the at least one threaded portion 352 of the screw engages with the threaded portions 312, 322 of the inductance block's first and second legs 310, 320 as shown in FIG. 3. When the screw 350 is screwed into the inductance block 301 this forms a conductive path 800 connecting the first contact plate 101 with the second contact plate 102 via the first leg 310, the second leg 320 and the at least one threaded portion 352 of the screw which is in contact with the threaded portions 312, 322 of the first leg and the second leg.

The conductive path 800 has an inductance, which may be adjusted by adjusting the height of the screw within the inductance block 301. By adjusting the height of the screw within the inductance block 301, the length of the conductive path 800 may be varied. Changing the length of the conductive path changes the inductance of the conductive path and thus the inductance of the inductance block 301.

FIG. 4A is a circuit diagram of an example apparatus according to the present disclosure. The apparatus includes a transistor amplifier 10 that is coupled to an input 410 of an impedance matching network 400. The output 490 of the inductance matching network may be coupled to a load 20. The impedance matching circuit 400 includes a variable inductor 401 on an input side of the circuit. The transistor amplifier 10 may correspond to the transistor amplifier 10 in FIG. 3 and the variable inductor 401 may correspond to the inductor block 301 and screw 350 in FIG. 3.

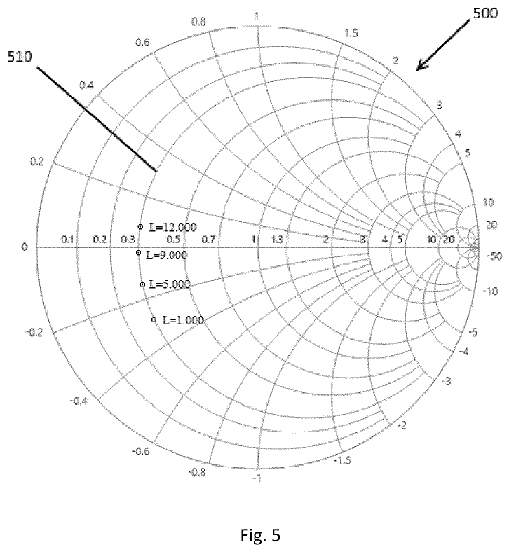

By varying the inductance of the inductor 401, the reactance presented by the impedance matching circuit may be varied without changing the resistance. That is the imaginary part of the impedance presented by the impedance matching circuit may be adjusted, while the real part of the impedance remains relatively constant. This is shown in FIG. 5 which is a Smith diagram 500 showing inductances at 1, 5, 9 and 12 nH for a frequency of 400 MHz. It can be seen that the inductances all lie on the same constant resistance circle, which in this case is Zo=0.3, but in other examples could be another constant value. As the inductance can be changed without changing the resistance, the use of a variable inductor makes it possible to change the reactance of the inductance matching circuit independently of the resistance. This facilitates fine tuning of the impedance matching.

The impedance matching network 300 or 400 shown in FIGS. 3 and 4A includes a single variable inductor by itself. However, in other examples the impedance matching network may include one or more further components, such as one or more capacitors and/or one or more fixed value inductors, in addition to the variable inductor. These further components may, for example, be formed on the inductance block or provided as a component of the circuit board.

In some examples the impedance matching network includes a plurality of components and the variable inductor is a first component on the input side of the impedance matching network with further components downstream of the variable inductor. As the variable inductor includes an inductance block with a high current rating it is able to receive a high current from a high power source and may dissipate heat effectively, while other more sensitive components may be included downstream.

FIG. 4B shows an example in which the impedance matching network 400 includes a capacitor 430 on an output side thereof and a transmission line 425 in series with the inductor 401. The capacitor 430 may have a fixed capacitance. The transmission line 425 may for example, be provided as a component of the circuit board, in the form of cable wire or PCB trace. The capacitor, 430 may for example, be provided as a component of the circuit board. The capacitor may for example be formed by a copper pattern on the printed circuit board or may be a discrete surface mounted device (SMD). In other examples the capacitor may be provided by an extension of the inductance block (not shown in FIG. 3).

In some examples the impedance matching network may be capable of compensating for a large mismatch in impedance. For instance, if the signal source has a low impedance, e.g. less than 1 Ohm, while the load 20 may have much higher impedance, e.g. 50 Ohms, this would give an impedance mismatch ratio of 50:1.

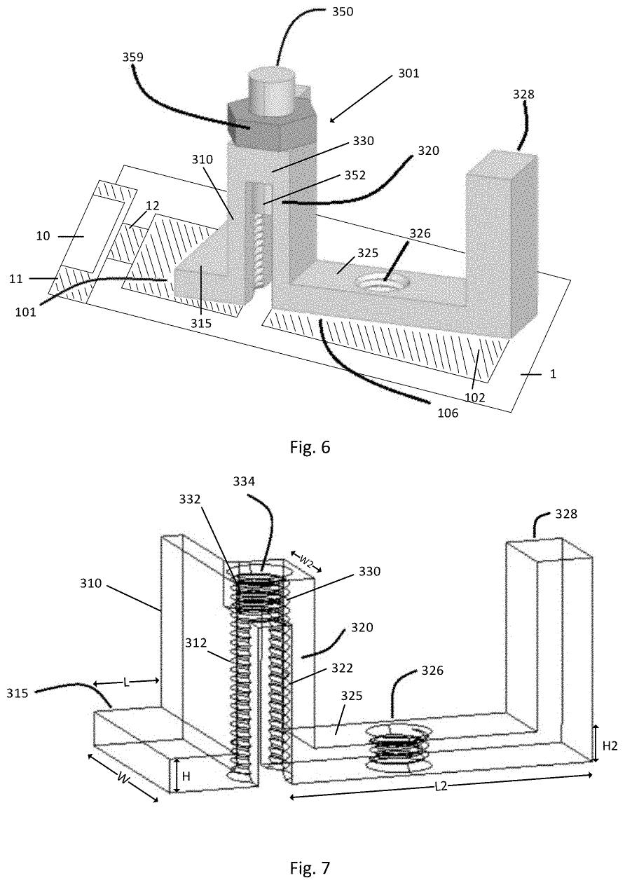

FIG. 6 shows a perspective view of a further example of an apparatus according to the present disclosure. The apparatus includes a circuit board 1, including a first contact plate 101 and a second contact plate 102 on which the first and second legs of an inductance block 301 are mounted. The apparatus also comprises an amplifier 10 which may, for example, be mounted on a conductive plate of the circuit board 1, or on the conductive plate of another circuit board.

A transistor amplifier 10 is coupled to the first contact plate 101, for example by a conductive line 12, which may for instance be an output pin of the amplifier. The conductive line 12 which couples the output of the amplifier to the input of the impedance matching network may be relatively wide, e.g. a width of 10 mm or greater. The first leg 310 of the inductance block may have a width equal to or greater than the width of the output pin of the amplifier. In some examples the first leg 310 may have a width of 10 mm or more, 15 mm or more or 20 mm or more. Having a relatively wide first leg 310 facilitates heat dissipation and enables the inductance block to have a high current rating (i.e. it is possible to receive a high current without overheating or damaging the inductor).

The inductance block 301 includes a first leg 310 and a second leg 320. The first and second leg project upwardly from the first and second contact plates 101, 102 of the circuit board 1. The first leg 310 and the second leg face 320 each other and are spaced apart and separated from each by an air gap. In the example of FIG. 6, the first and second legs are joined by a bridge 330.

The inductance block comprises an electrically conductive material. The inductance block may be formed of a material having a high thermal conductivity and high specific heat capacity in order to promote heat dissipation. In one example, the inductance block is formed of a metal material, such as but not limited to copper or a copper alloy.

In FIG. 6 the bridge 330 links the first leg 310 and the second leg 320 at the top, so that the inductance block 301 has an inverted U-shape. The bridge 330 includes an aperture (not shown in FIG. 6) for receiving a screw 350, which is inserted through the aperture between the first and second legs and screwed into the inductance block. A nut 359 may be provided for fastening the screw 350 in place. For example the nut 359 may be screwed onto the top of the screw 350 above the bridge 330 to secure the screw in place.

The first leg 310 may include a foot 315 extending laterally away from the main body of the first leg. Likewise the second leg 320 may include a foot 325 extending laterally away from the main body of the second leg. The foot 315 of the first leg may extend outward in a direction away from the second leg, while the foot 320 of the second leg may extend outward in a direction away from the first leg. The feet 315, 320 makes it easier to mount the inductor block 301 to the first and second contact plates of the circuit board. The feet 315, 320 also facilitate heat dissipation.

In the example of FIG. 6, the inductance block 301 further includes a stub capacitor 328 extending upwardly from the foot 325 of the second leg. The stub capacitor 328 may act as a capacitor of the impedance matching network and may correspond to the capacitor 430 shown in the circuit diagram of FIG. 4. In other examples the impedance block may not have a stub capacitor and the capacitor 430 may be implemented by a separate capacitor device mounted to or embedded in the circuit board 1. In still other examples, the impedance matching network may not include a capacitor.

The foot 325 of the second leg may correspond to the transmission line 425 of the impedance matching circuit shown in FIG. 4B. The foot 325 has as length L2 and may be relatively long, e.g. over twice the length of the bridge 330 between the first and second legs. The foot 325 of the second leg may include an aperture 326 for receiving a fastening screw to attach the inductance block 301 to the circuit board 1.

FIG. 7 shows the inductance block 301 in more detail. Like reference numerals denote like parts as in FIG. 6. As the screw 350 is not shown in FIG. 7, the aperture 334 in the bridge 330 can be seen more clearly. The aperture extends through the bridge 330 to the air gap between the first and second legs below. The aperture 334 may include screw threads 332 which may be aligned with the threads 312 of the first leg and the threads 322 of the second leg to facilitate screwing of a screw into the inductance block.

The width W of the first leg 310 may be at least one and a half times greater than a diameter of the screw 350. For example, if the screw is an M5 screw having a diameter of 5 mm, then the first leg may have a width of 8 mm or more. In some examples the width W of the first leg may be at least two or at least three times greater than the diameter of screw 350. In one example the width W of the first leg is 15 mm or greater, while the diameter of the screw 350 is 4 mm. This increases the surface area of the inductance block and thus helps to improve heat dissipation.

In some examples, the width W of the first leg 315 is at least two times greater than a width of the second leg. This helps to maximize surface area on the input side of the inductance block and so improve heat dissipation. In some examples, the width W1 of the first leg is at least 15 mm.

The height H of the foot 315 of the first leg may be selected so as to provide adequate heat dissipation. In one example the height H is at least 2 mm. The length L of the foot 315 may be selected to provide steady mounting of the first leg on the first contact plate 101 of the circuit board and/or to improve heat dissipation.

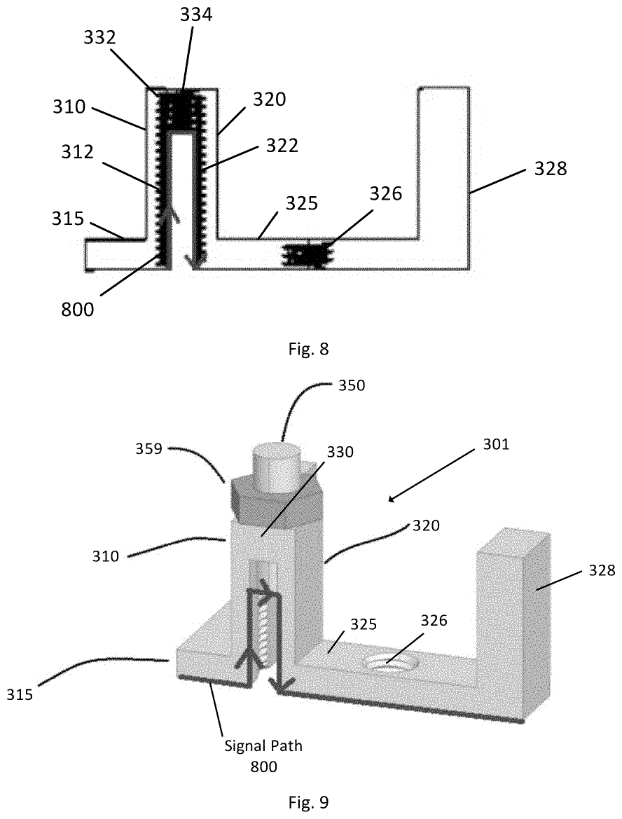

FIG. 8 is a diagram showing a conductive path 800 through the inductor block 301 of FIG. 7 when no screw is screwed into the aperture 334 of the inductor block. For example, the conductive path 800 may be a path taken by a signal output from the transistor amplifier into the impedance matching network. As can be seen in FIG. 8, the signal travels up the first leg 310, across the bridge 330 and down the second leg 320. As no screw is screwed into the inductance block, the conductive path is at maximum length and the inductance of the conductive path and therefore the inductance of the inductance block is at a maximum.

FIG. 9 illustrates an inductor assembly comprising the inductor block 301 of FIG. 7 together with a screw 350. Like reference numerals indicate like parts as in FIGS. 6 and 7. The screw 350 is screwed into the inductor block, so that at least one threaded portion of the screw 350 is contact with threaded portions of the first leg 310 and the second leg 320. As a result, the screw together with the inductance block form a conductive path 800 which traverses the first leg 310 of the inductor block, the screw 350 and the second leg 320 of the inductor block. As the screw 350 is screwed part way down into the inductor block 301, the length of the conductive path 800 is shortened compared to that shown in FIG. 8. Therefore the inductance of the conductive path 800 and the effective inductance presented by the inductor block 301 to the input signal is less than in FIG. 8.

The inductance of the conductive path is in part dependent on the length of the conductive path 800. Therefore by adjusting the height of the screw 350, i.e. adjusting the depth to which the screw 350 is screwed into the inductance block 301, the inductance of the conductive path 800 may be adjusted. In this way the effective inductance presented by the inductance block to the input signal may be varied.

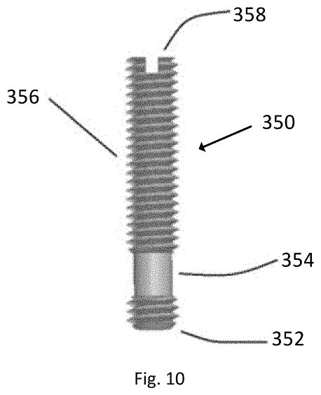

FIG. 10 shows an example design of the inductance adjustment screw 350 which is to be screwed into the inductance block 301 in order to vary the inductance of the inductance block. The screw 350 includes a first threaded portion 352, a second threaded portion 356 and a thread free shank portion 354 in-between the first threaded portion and the second threaded portion. The thread free shank portion 354 may be thought of as a thread clearance zone. The top end of the screw may have a notch 358 for receiving a screw driver to facilitate screwing of the screw into the inductance block. The screw may be formed of a metal, such as but not limited to copper or a copper alloy.

The first threaded portion 352 is located towards the distal end of the screw and may extend to the tip of the screw. When the screw is screwed into the inductance block, the conductive path passes through the first threaded portion 352. The presence of the thread free shank portion, which is not in contact with the conductive threads of the first and second legs of the inductance block, helps to confine the conductive path to the first threaded portion 352 and thus provide a stable and more predictable inductance. In contrast, if the entire screw was threaded, then conductive path would be less predictable as electric current could pass through any part of the screw in contact with the inductance block.

The conductive path does not pass through the non-threaded shank portion 354 as the shank portion is not in electrically conductive contact with the first leg 310 or the second leg 320. The thread free shank portion 354 may have a smaller diameter than the first and second threaded portions 352, 356 so that it does not contact the threads of the first leg or the second leg. The conductive path passes through the first threaded portion 352, rather than the second threaded portion 356, because the first threaded portion is deeper into the inductance block 301 and has a lower height than the second threaded portion 356. Electric current has a tendency to flow via the shortest path, which in this case is through the first threaded portion which is nearer to the distal end of the screw.

Therefore, by providing first and second threaded portions and a thread free shank, the length and inductance of the conductive path may be kept stable and controlled with a relative degree of precision. To provide further predictability and precision, the first threaded portion may be relatively short to confine the conductive path to a smaller area. In one example, the length of the first threaded portion is 5 mm or less. In another example the length of the first threaded portion is 2 mm or less.

The second threaded portion 356 is longer than the first threaded portion and may be several times longer, e.g. at least 3 times as long. In some examples the second threaded portion may extend substantially all the way from the shank portion 354 to the upper end of the screw. Having a longer second threaded portion enables a large range of adjustment of the height of the screw and therefore a large range of inductance for the inductance block. The second threaded portion may also be used as a thread shaft for the locking nut 359.

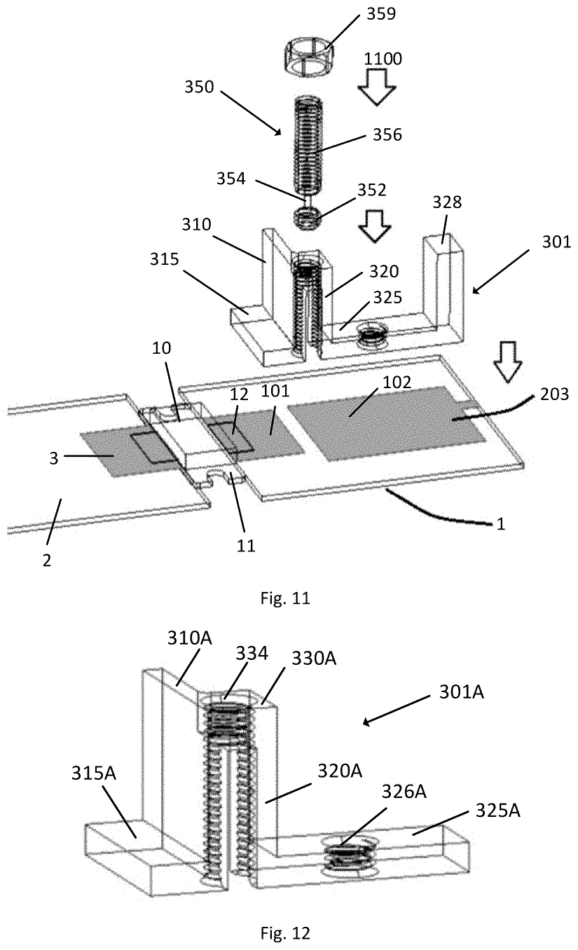

FIG. 11 shows a method of manufacturing the apparatus of FIG. 6. Like reference numerals denote like parts as in FIG. 6. In the example of FIG. 11 it can be seen that the transistor amplifier 10 is mounted to a base 11 which is positioned between the first circuit board 1 and another circuit board 2. In the illustrated example an input pin of the transistor amplifier 10 is connected to the circuit board 2, while an output pin 12 of the transistor amplifier 10 is connected to the first contact plate 11 of the first circuit board 1. However, in other examples the power transistor amplifier 10 could be mounted to the first circuit board 1 or to the second circuit board 2 or to another location. As shown by the arrows 1100, the inductance block 301 is to be mounted to the first circuit board 1 with the first leg 310 mounted to the first contact plate 101 and the second leg mounted to the second contact plate 102.

The inductance block 301 may be soldered to the first contact plate 101 and the second contact plate 102 and fixed to the circuit board 1 by a fastening screw (not shown) which extends through the aperture 326 of the foot 325 of the second leg and into the circuit board 1. In one example, the legs of the inductance block 301 are first soldered to the contact plates of the circuit board and the inductance block is subsequently secured to the circuit board by use of the fixing screw. This helps to prevent scratching of the contact plates and/or circuit board while the inductor block is screwed in place. If the inductance block was attached by a screw without first soldering, then the inductance block could move and scratch the contact plates and/or circuit board.

The present disclosure has been described above with reference to several illustrative examples. However, it is to be understood that a person skilled in the art may make variations or modifications to the above examples, while still remaining within the scope of the present disclosure.

For example, the screw of FIG. 10 could be modified to include only one threaded portion, instead of two threaded portions separated by a thread free shank. Further, various modifications to the inductance block shown in FIGS. 4 to 9 and 11 are possible and examples of alternative designs of inductance block are shown in FIGS. 12 to 14.

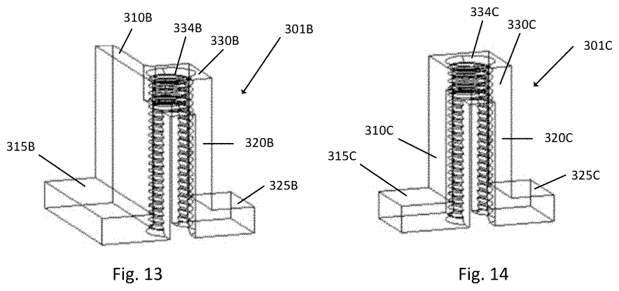

In FIGS. 12 to 14 reference numerals of the same number but with suffix A, B or C respectively refer to like parts as the corresponding reference numerals without suffix in FIG. 7. FIG. 12 shows an example inductance block 301A, which is similar to the inductance block of FIG. 7, but which does not include a stub capacitor on the foot of the second leg. FIG. 13 shows another example inductance block 301B, which is similar to the inductance block of FIG. 12, but which does not include an aperture in the foot of the second leg. FIG. 14 shows an example inductance block 301C, which is similar to the inductance block of FIG. 13, but in which the width of the first leg is substantially the same as the width of the second leg. Other variations and or combinations of the above features are possible. For instance, the inductance block of FIG. 15 could be modified to lengthen the foot of the second leg and/or include an aperture in the foot of the second leg for securing the inductance block to a circuit board. The above are just several examples and other modifications could be made while remaining within the scope of the present disclosure as defined by the claims.

1. An apparatus comprising a transistor amplifier and an impedance matching network, the impedance matching network comprising:
a circuit board including a first contact plate and a second contact plate;
an inductance block comprising a first leg mounted on the first contact plate and projecting upwardly from the first contact plate, a second leg mounted on the second contact plate and projecting upwardly from the second contact plate, wherein the second leg is separated from the first leg by an air gap and the first leg and the second leg include threaded portions for receiving a screw;
a screw comprising a shaft with at least one threaded portion, the screw being screwable into the inductance block such that the at least one threaded portion of the screw engages with the threaded portions of the first leg and the second leg;
the screw and the inductance block together forming a conductive path connecting the first contact plate with the second contact plate via the first leg, the second leg and the at least one threaded portion of the screw which is in contact with the threaded portions of the first leg and the second leg, said conductive path having an inductance, wherein a length of the conductive path and a value of the inductance of the conductive path are adjustable by adjusting a height of the screw within the inductance block;
and wherein the amplifier comprises an output which is coupled to the first contact plate of the circuit board of the impedance matching network.

2. The apparatus of claim 1 wherein the inductance block has an inverted U-shape and includes a bridge joining the first leg with second leg, said bridge including an aperture for receiving the screw.

3. The apparatus of claim 1 wherein the screw comprises a first threaded portion, a second threaded portion and a thread free shank portion in-between the first threaded portion and the second threaded portion, said conductive path passing through the first threaded portion.

4. The apparatus of claim 1 wherein a width of the first leg is at least three times greater than a diameter of the screw.

5. The apparatus of claim 1 wherein a width of the first leg is at least two times greater than a width of the second leg.

6. The apparatus of claim 1 wherein a width of the first leg is the same or greater than the width of an output pin of the amplifier.

7. The apparatus of claim 1 wherein a width of the first leg is at least 8 mm.

8. The apparatus of claim 1 wherein the first leg includes a foot which is mounted to the first contact plate, the foot extending laterally from a main body of the first leg and having a height of at least 2 mm.

9. The apparatus of claim 1 wherein the screw has a notch at a top end thereof for receiving a screw driver.

10. The apparatus of claim 1 further comprising a nut for fastening the screw in place.

11. The apparatus of claim 1 wherein the second leg includes a foot which is mounted to the second contact plate, the second foot extending laterally from a main body of the second leg.

12. The apparatus of claim 11 wherein the impedance block further includes a stub capacitor extending upwardly from the foot of the second leg.

13. The apparatus of claim 11 wherein the foot of the second leg includes an aperture for receiving a fastening screw to attach the inductance block to the circuit board.

14. The apparatus of claim 13 wherein the impedance block is soldered to the first contact plate and the second contact plate and fixed to the circuit board by a fastening screw which extends through the aperture of the foot of the second leg and into the circuit board.

15. An inductor assembly for use in an impedance matching circuit, the inductor assembly comprising:
a metal inductance block having an inverted U-shape comprising a first leg for mounting on a first contact of a circuit board, a second leg for mounting on a second contact of a circuit board, the second leg being separated from the first leg by an air gap and being connected to the first leg by a bridge joining the first leg and the second leg, the bridge including an aperture and the first leg and the second leg including threads;
a metal inductance adjustment screw comprising a shank with a first threaded portion, a second threaded portion and a thread clearance zone without threads between the first threaded portion and the second threaded portion, the metal inductance adjustment screw being insertable into the aperture of the bridge and screwable into the threads of the first leg and the second leg;
wherein the inductance block and the inductance adjustment screw together form a conductive path which traverses the first leg, the first threaded portion and the second leg, said conductive path having a variable inductance which is adjustable by adjusting a height of the inductance adjustment screw within the inductance block.

16. The inductor assembly of claim 15 wherein the first threaded portion is at a distal end of the metal inductance adjustment screw and wherein the distal end is inserted into the aperture of the bridge of the metal inductance block.

17. The inductor assembly of claim 15 wherein a length of the first threaded portion is less than a length of the second threaded portion.

18. The inductor assembly of claim 15 wherein a width of the first leg is at least two times greater than a width of the second leg.

19. The inductor assembly of claim 15 wherein a first foot extends laterally from the first leg and a second foot extends laterally from the second leg.

20. The inductor assembly of claim 19 wherein a stub capacitor projects upwardly from the second foot.
